(19) United States
(12) Patent Application Publication
(10) Pub. No.: US 2002/0005533 A1
(43) Pub. Date: Jan. 17, 2002

(54) SUBSTRATE PLATE TRENCH DRAM CELL WITH LIGHTLY DOPED SUBSTRATE

(76) Inventors: DONALD M. KENNEY, SHELBURNE, VT (US); PAUL C. PARRIES, WAPPINERS FALLS, NY (US)

Correspondence Address: IBM MICROELECTRONICS, INTELLECTUAL PROPERTY LAW, 1000 RIVER STREET, 972 E, ESSEX JUNCTION, VT, 05452, US

(21) Appl. No.: 09/222,652

(22) Filed: Dec. 30, 1998

Related U.S. Application Data
(60) Provisional application No. 60/070,172, filed on Dec. 31, 1997.

(51) Int. Cl. H01L 27/108

(52) U.S. Cl. 257/296

(57) ABSTRACT

A DRAM semiconductor device wherein a substrate plate trench (SPT) memory cell is formed in an N⁻-type substrate, without an epitaxial layer in which the substrate is biased at circuit ground in order to ensure that the substrate surrounding the trench capacitors is biased into accumulation in order to avoid unacceptable loss of storage node capacitance which would be caused by allowing the substrate to go into depletion.

Thus, the manufacturing cost of the DRAM devices is reduced substantially by not requiring a heavily doped substrate and by not including the epitaxial layer used in previous SPT DRAM cells.

### CROSS REFERENCE TO RELATED APPLICATIONS

This non-provisional application is based on and claims priority of Provisional Application No. 60/070,172 filed on Dec. 31, 1997.

### BACKGROUND OF THE INVENTION

1. Field of the Invention

This invention relates to semiconductor memory devices and particularly to high density dynamic random access memory cells and methods for their manufacture in sub-micron technologies.

2. Description of the Prior Art

Designers of technologies for producing semiconductor devices have been continually pressure to increase effective device densities in order to remain cost and performance competitive. As a result, VLSI and ULSI technologies have entered the sub-micron realm of structural dimensions and now are designing technologies in the nanometer feature size range. In the foreseeable future absolute atomic physical limits will be reached in the conventional two-dimensional design approach to semiconductor device design. Traditionally, Dynamic Random Access Memory (DRAM) designers have met the severest of challenges in advancing technologies by pushing the limits of feature size resolution with each generation of DRAM. For example, designers of 64 K bit DRAMs were perplexed to learn that a practical physical limit to charge capacity of storage capacitors had already been reached due to the minimum charge capacity required to allow reliable data signal sensing in the presence of naturally occurring atomic particle radiation inherently present in fabrication materials and the operating environment. Storage capacitors in the range of about 50 femtofarads are now considered to be a physical limit. From a practical view, this limitation prevented a continuation of the scaling of DRAM dimensions and voltages initiated in the early 1970s. Reduction in the surface area of semiconductor substrate utilized by the DRAM storage capacitor has been severely restricted. Due to decreases in the thickness of reliable capacitor dielectric materials, existing 1 Megabit (1 Mb) DRAM technologies continue to enjoy the freedom of planar, two-dimensional device and circuit design. Beginning with 4 Mb DRAMs, the world of three-dimensional design has been utilized to the extent that the simple single device/capacitor memory cell has been altered to provide the capacitor in a vertical dimension. In such designs, the capacitor has been formed in a trench formed in the surface of the semiconductor substrate. In yet denser designs, other forms of three-dimensional capacitors have been proposed, such as stacking the plates of the capacitor above the transfer device. Such designs, however, present difficulties in forming the interconnections to the required word access and data bit lines to the DRAM memory cell. Additional designs have been proposed in which the transfer device and its associated capacitor are both formed within a trench of preferably minimum feature size. Currently, insurmountable processing difficulties make such designs impractical for product manufacturing processes.

A large number of proposals for 16 Mb and greater density DRAM cell designs have avoided continuing development of trench cell technology because of the existence of charge leakage mechanisms known to be present in trench capacitor structures. As these leakage mechanisms have become known, extensions of trench DRAM cells designs have been used successfully in 16 Mb designs.

The following references describe various aspects of prior art techniques used in DRAM and other semiconductor technologies.

The article “Trench and Compact Structures for DRAMs” by P. Chatterjee et al., International Electron Devices Meeting 1986, Technical Digest paper 6.1, pp. 128-131, describes variations in trench cell designs through 16 Mb DRAM designs, including the Substrate Plate Trench (SPT) cell described in more detail in U.S. Pat. No. 4,688,063 issued Aug. 18, 1987 to Lu et al. and assigned to the assignee of the instant invention. The SPT cell uses a highly conductive substrate as the DRAM cell plate. The storage node of each cell is formed in a deep trench in the substrate.

U.S. Pat. No. 4,801,988 issued Jan. 31, 1989 to Kenney and assigned to the assignee of the instant invention, describes an improved SPT cell which includes a thick isolation region formed within the trench to enable higher density packing of DRAM cells.

The article “CMOS Semiconductor Memory Structural Modification to Allow Increased Memory Charge,” anonymous, IBM Technical Disclosure Bulletin, Vol. 31, No. 11, April 1989, pp. 162-5, teaches a method of isolating the substrate plate of an SPT cell from support devices by providing a buried region under support devices in order to allow the plate reference voltage to be separately biased at an optimum Vdd/2 volts. This design is subject to leakage current generation between the substrate and the storage node which is unacceptable in a manufacturable product. The required V/2 substrate bias also requires a heavily doped substrate with a lower doped epitaxial layer. Such heavily doped N+ type substrates are not routinely offered by wafer manufacturers due to difficulties in their manufacture and are very expensive to manufacture.

U.S. Pat. No. 4,912,054 issued Mar. 27, 1990 to Tomassetti describes methods of isolating bipolar-CMOS circuit devices through the use of various epitaxial layers as commonly found in bipolar device technologies. The article “A 45-ns 16-Mb DRAM with Triple-Well Structure” by S. Fujii et al., IEEE Journal of Solid-State Circuits, Vol. 24, No. 5, October 1989, pp. 1170-1175, describes techniques for isolating various different functional device types in which the entire array of trench DRAM cells is formed within a surface implanted P-well.

U.S. Pat. No. 4,829,017 issued May 9, 1989 to Malhi describes a method of forming a buried doped layer in a substrate by forming a shallow trench, protecting its sidewalls, further extending the trench and finally doping the walls of the extended trench to form a continuous doped region useful as the storage node of a trench DRAM.

The article “New Well Structure for Deep Sub-micron CMOS/BiCMOS Using Thin Epitaxy over Buried Layer and Trench Isolation” by Y. Okazaki et al., 1990 Symposium on VLSI Technology, Digest of Technical Papers, paper 6C-4, pp. 83-4, describes the use of buried epitaxial layers to isolate surface devices from the substrate.

The following references relate specifically to variations in SPT DRAM cells in which a buried region of opposite conductivity type from the substrate is used a one plate of the DRAM storage capacitor. U.S. Pat. No. 4,918,502 issued Apr. 17, 1990 to Kaga et al. describes a buried plate trench DRAM cell in which the storage node of the cell and a sheath plate are formed in a single trench. At the bottom of the trench a diffusion of opposite type from the substrate is formed such that the diffusions of adjacent cells interconnect forming a grid-like structure. One or more trenches not associated with a DRAM cell is formed to act as a reach through to enable the doped region to be biased at a suitable reference voltage. FIG. 12, thereof, clearly illustrates the grid-like aspect of the buried region. European published application EP 0 283 964, published Sep. 28, 1988 describes a buried plate SPT DRAM cell in which an out-diffused region from the DRAM trenches, similar to that in Kaga et al., in which the diffused region forms the plate of the SPT cell. As in Kaga et al. a grid-like region is formed and is contacted by a non-cell trench. U.S. Pat. No. 4,873,560 issued Oct. 10, 1989 to Sunami et al, describes yet another buried plate SPT cell in which the access transistor is formed in the cell trench. FIG. 30, thereof, and its related text, describes the importance of maintaining the grid-like structure of the buried region in order to enable proper operation of the cell transfer device. Sunami et al, further cautions that in the event that opening in the grid-like buried region should be “filled by the depletion layer” isolating the surface devices from the substrate a separate connection can be made to the “isolated” surface region in order to bias it to the same potential as the substrate. UK Patent Application GB 2 215 913 A, published Sep. 27, 1989 describes yet another variation in the buried SPT DRAM cell design in which the dopant for the buried region is provided by ion implantation into the sidewalls of the deep trench of the DRAM cell.

Finally, U.S. Pat. No. 4,794,434 issued Dec. 27, 1988 to Pelley, describes a buried plate SPT DRAM cell formed using bipolar device processing methods in which the buried plate region is formed from a buried sub-collector structure normally part of a bipolar transistor.

While the above cited references illustrate the diverse and concentrated efforts made by DRAM designers in attempting to overcome the inherent barriers in continuing to reduce the size, and increase the density, of DRAM cells, none provide the capability to carry DRAM technology into the sub-0.5 micron feature size range, a feat which must be achieved in order to continue the two decade “tradition” of providing ever increasing density of DRAM technology. Out of frustration, DRAM designers have turned to the process-complicating use of “stacked capacitor” DRAM cells only to find such designs extremely cumbersome to the point of being virtually un-manufacturable.

The subject invention addresses the unsolved problems of the prior art by providing solutions to problems presented by extending the manufacturability of the simple SPT cell to 64 Mb DRAM and beyond.

### SUMMARY OF THE INVENTION

An object of the invention is to provide a buried plate SPT DRAM cell array in which the density limitations of the prior art are removed.

Another object of the invention is to reduce the complexity of SPT DRAM design to allow process simplicity and thus increased product yield.

Yet another object of the invention is to provide a buried plate SPT DRAM cell which has a minimum impact on existing processing technologies.

The present invention relates to methods for providing a cell design in which all of the historically limiting parameters of DRAM cells are dealt with in a unifying manner to provide a near optimum design in which charge leakage factors are minimized and device bias conditions are optimized.

The invention includes a substrate plate trench DRAM cell array in which a buried plate electrode is formed in a lightly doped semiconductor substrate such that the cell transfer device can be operated independently from other support devices formed in the substrate. The use of a lightly doped substrate reduces the cost of manufacture of DRAMs by eliminating expensive epitaxial layers and the need for complex processing steps. Sub-half micron feature sizes are used cooperatively with diffusion techniques to provide a simple buried layer formation process impossible at larger feature size dimensions.

These and other objects and features of the invention will become more fully apparent from the several drawings and description of the preferred embodiment.

### DESCRIPTION OF THE DRAWINGS

FIG. 1 illustrates by way of a cross section, the SPT DRAM cell of the invention showing the relationship between the lightly doped substrate and the dopant wells formed in the surface of a semiconductor wafer.

FIGS. 2-5 are cross sectional views of the cell of FIG. 1 in various stages of its fabrication.

### DESCRIPTION OF THE PREFERRED EMBODIMENT

The memory cell of our U.S. Pat. No. 5,264,716 provides a method for fabricating an NMOS SPT cell in a p-type substrate wafer. The IBM Technical Disclosure Bulletin, Vol. 31, No. 11, April 1989, pp. 162-5, shows an SPT cell design requiring a heavily doped substrate that could be used to make an NMOS array of SPT cells on an n-type wafer having an N+-type epitaxial layer on its upper surface.

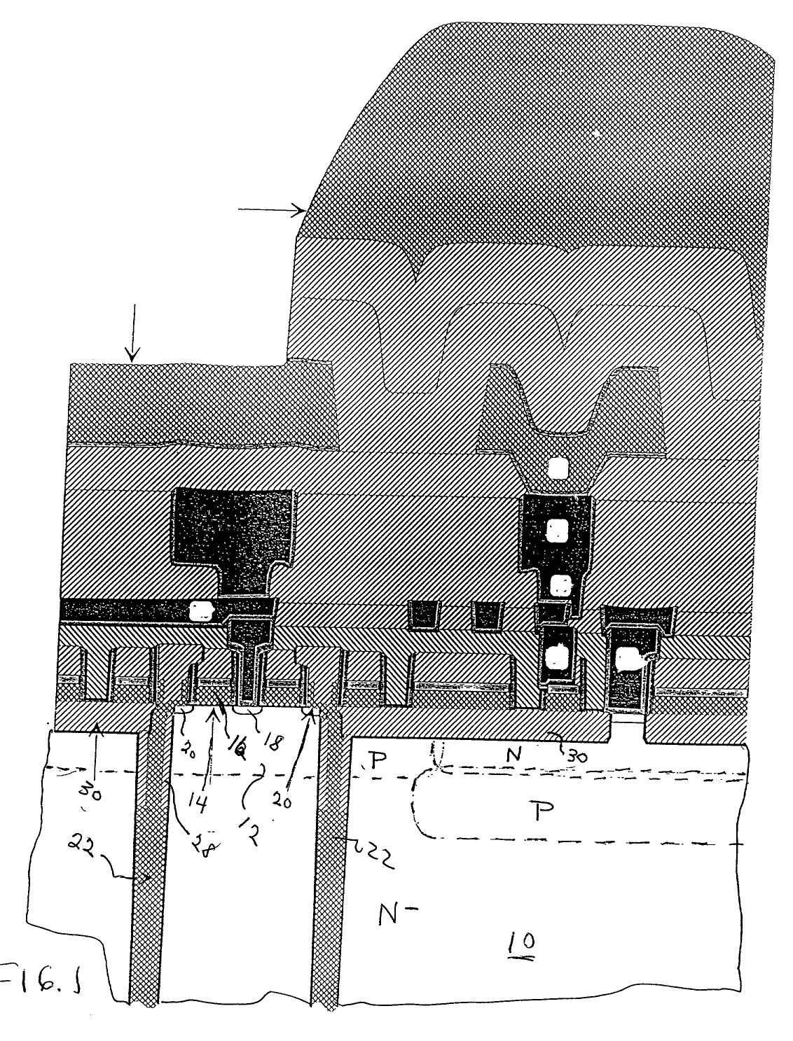

The SPT cell of this invention provides an NMOS array SPT design which requires a simple N⁻type (herein after designated as N−/type) substrate without the need for an epitaxial layer. The cell is shown in cross section in FIG. 1.

The n−/type substrate of this invention is operated with a substrate bias of circuit ground potential and has a storage node voltage swing of zero (ground) to +Vdd volts. Thus, the N−/type substrate will always be biased into accumulation so as to avoid unacceptable loss of storage node capacitance due to depletion of the substrate in the vicinity of the storage node trench. The cell design uses appropriately biased double junction isolation wells in some non-array or support device regions.

The n−/type substrate of this invention is operated with a substrate bias of circuit ground potential and has a storage node voltage swing of zero (ground) to +Vdd volts. Thus, the N−/type substrate will always be biased into accumulation so as to avoid unacceptable loss of storage node capacitance due to depletion of the substrate in the vicinity of the storage node trench. The cell design uses appropriately biased double junction isolation wells in some non-array or support device regions.

The n−/type substrate of this invention is operated with a substrate bias of circuit ground potential and has a storage node voltage swing of zero (ground) to +Vdd volts. Thus, the N−/type substrate will always be biased into accumulation so as to avoid unacceptable loss of storage node capacitance due to depletion of the substrate in the vicinity of the storage node trench. The cell design uses appropriately biased double junction isolation wells in some non-array or support device regions.

Referring to FIG. 1, there is shown the basic elements of the SPT of the invention. The cell is an improvement of the prior art SPT DRAM cells as described by Lu et al. in U.S. Pat. No. 4,688,063, as modified by Kenney in U.S. Pat. No. 4,801,988, and as further modified by Kenney in U.S. Pat. No. 5,246,716 each of which are incorporated herein by reference. The cell includes the following major features. A substrate 10 of N−/type semiconductor has an P-type well 12 formed at its upper surface into which N-channel transfer devices 14 are formed. The preferred impurity concentration of the substrate is between 1-2 10¹⁶ atoms of n-type dopant per cubic centimeter. A transfer or control gate electrode 16 of device 14 is responsive to a word access line of the DRAM array support circuits, not shown, to couple data between data or bit line diffused N-type region 18 and diffused N-type storage node region 20 through the channel region formed in P-well 12. In a manner similar to the prior art, a storage capacitor is formed in a deep trench 22 adjacent to the storage node 20 and includes a signal storage node formed by conductive N-type polysilicon electrode 24 provides the storage node capacitance in a Deep Trench (DT) isolated from substrate 10 by a thin dielectric layer. Diffused surface storage node 20 and signal storage node region 24 in the trench 22 are connected by a conductive buried strap. At the top of the storage trench a thick insulating collar 28 is provided to increase the threshold voltage of the vertical parasitic FET formed by the diffused storage node 20 and the substrate within the P-well 12. Local surface isolation regions 30 are provided, as desired, to define active device regions of the surface of the substrate.

With the exception of the semiconductor type of the substrate 10 and the presence of the implanted p- and -wells, the cell has similar attributes as the N-channel variant of the prior art SPT DRAM cell. It will be recognized, that the local substrate region of the cell transfer device 14 can be independently biased by reference voltage Vbp. Similarly, the substrate bias Vsub is biased at local or circuit ground potential.

It is an important aspect of the invention to provide arrays of cells as described in connection with FIG. 1 in a simple easy to manufacture processing sequence.

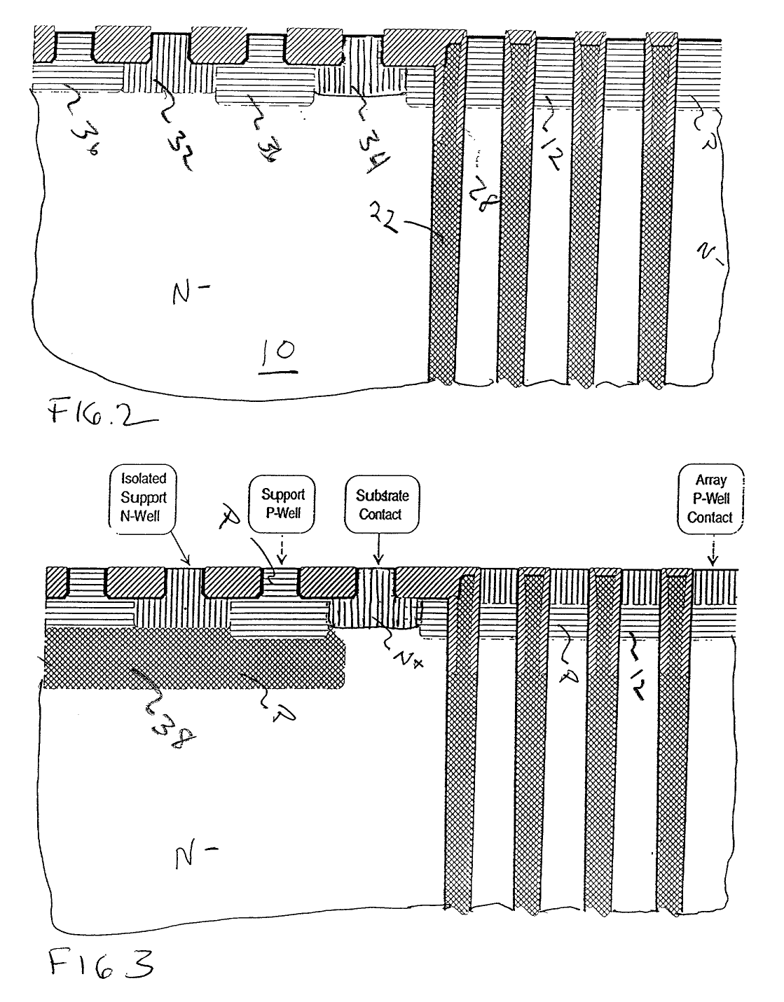

Reference is now made to FIGS. 2-6 which describe the preferred process sequence used to fabricate the diffused buried plate trench DRAM cell array.

The initial process steps, including the formation of the deep storage trenches, are identical as those taught in our patent U.S. Pat. No. 5,264,716 FIGS. 3-11 except that the n-type regions 32 and 34 (of U.S. Pat. No. 5,264,716) are not formed as the substrate in this invention is already n−/type.

Referring now to FIG. 2 which shows a slightly different cross sectional view of the semiconductor substrate illustrating the ion implantation steps necessary to form a substrate contact and junction-isolated n-well for support circuits. The process continues with a semiconductor substrate 10 comprising a silicon wafer having an n-type impurity concentration of 1-2×10¹⁶ atoms per cubic centimeter. It should be noted that the substrate requires no epitaxial layers as do most prior art buried plate DRAM cell designs. In addition, the concentration level is at least three orders of magnitude lower than that required by prior art designs.

In order to form the array and support n-well regions an N-Well mask NW is formed on the surface of substrate 10. First a p-type threshold voltage implant of boron is implanted at 12 KEV at a dose of about 6.5×10¹² atoms per square centimeter and then phosphorous is implanted at 500 KEV at a dose of about 2.5×10¹³ atoms per square centimeter to form regions 32 and 34. Region 32 will become an isolated n-well and region 34 forms a substrate contact which will be biased circuit ground potential. Next, following the removal of the NW mask, a p-channel device threshold voltage implant is formed in selected n-well regions 32 by implanting n-type impurity, arsenic, using a selective NH mask. This is accomplished by implanting arsenic at 220 KEV at a dose of about 2.0×10¹² atoms per square centimeter into selected regions where p-wells will be formed.

Following the removal of the NH mask a p-well defining mask is formed on the substrate. The p-wells are retrograde doped, well known in the art and include three different implants of p-type dopant boron as follows. A field tailoring implant at 150 KEV at a dose of about 1.3×10¹³ atoms per square centimeter; a punch through implant at 80 KEV at a dose of about 1.6×10¹² atoms per square centimeter; and threshold voltage control implant at 12 KEV at a dose of about 5.0×10¹² atoms per square centimeter are provided to form p-well regions 12 and 36. Region 12 forms the array area and regions 36 will form lateral isolation regions for n-wells 32.

Referring now to FIG. 3, a mask P1 is used to define regions 38 of deep p-type used to provide vertical n-well isolation. Regions 38 are formed by implanting boron at 700 KEV at a dose of about 5.0×10¹³ atoms per square centimeter.

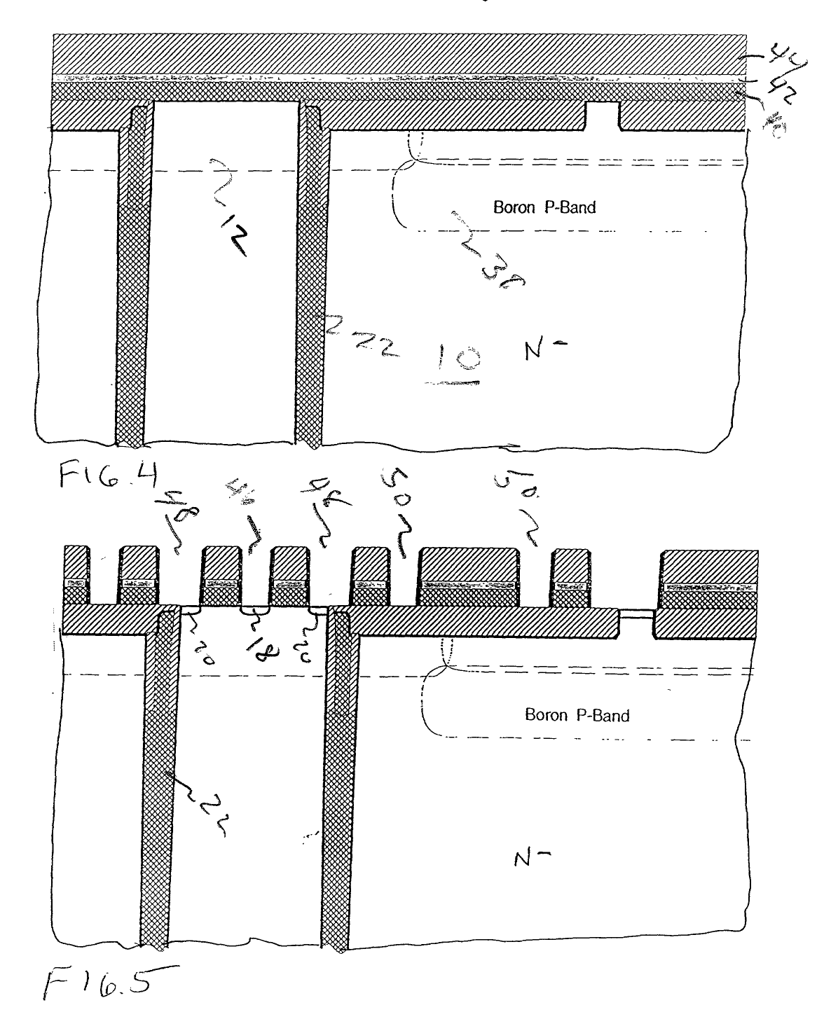

Next, referring to FIG. 4 the gate stack is formed according, for example, to the method described in U.S. Pat. No. 5,264,716, and comprises a thin gate oxide (not shown), a polysilicon gate layer 40, a silicide conductivity enhancing layer 42 and gate stack insulator comprising plasma enhanced CVD (PECVD) silicon dioxide 44.

Next, as shown in FIG. 5, the gate stack is etched to define the gate structures and openings 46-50. Openings 46 will be used to form bit line contacts, openings 48 will be used to form a polysilicon strap connecting the DRAM storage node diffusion 20 to the capacitor storage plate in trench 22, and opening 50 to further delineate the remaining polysilicon regions.

Now, referring again to FIG. 1, the p- and n-channel CMOS devices and DRAM cell structure are completed by the formation of ion implanted diffusion regions 18 and 20 by standard techniques. These steps are accomplished in a manner as taught in U.S. Pat. No. 5,466,636 to Cronin et al. issued on Nov. 14, 1995, herein incorporated by reference.

The DRAM is completed by providing a number of additional planarized interconnect levels, as required by the complexity of the circuits to be interconnected. These techniques use the CMP technology as taught in U.S. Pat. No. 4,789,648 to Chow et al., issued Dec. 6, 1988, and U.S. Pat. No. 4,944,836 to Beyer et al., issued Jul. 31, 1990, both herein incorporated by reference.

While the invention has been described in terms of a single preferred embodiment, those skilled in the art will recognize that many of the steps described above can be altered and that dopant species and types as well as other material substitutions can be freely made without departing from the spirit and scope of the invention.

What is claimed is:

1. A dynamic random access memory device comprising:
a semiconductor substrate having a major body region with a dopant impurity level on the order of 1-2×10¹⁶ atoms per cubic centimeter of a first conductivity type;
at least one array of dynamic memory cells, each cell comprising an access transistor coupled to a storage capacitor, the transistor of each memory cell being formed within a second region of said semiconductor substrate, each access transistor having a control electrode, a data line contact region, a storage node region, and a channel region; and
a plurality of signal storage capacitors formed in a plurality of trenches in said substrate, each capacitor including a signal storage node region and a reference voltage node region separated by a dielectric insulator, the reference voltage node region being formed in said first region of said substrate and the signal storage node region of each capacitor being connected to a corresponding storage node region of one of said access transistors.

2. The dynamic random access memory device of claim 1 wherein the first region of the substrate is biased at circuit ground potential.

3. The dynamic random access memory device of claim 2 wherein the impurity type of said first region is N-type.

4. The dynamic random access memory device of claim 3 wherein the impurity type of the first region is arsenic.

5. The dynamic random access memory device of claim 1 wherein each of said storage capacitors includes an insulating collar which extends from the surface of the second region to the first region of the substrate.
